(19) United States
(12) Patent Application Publication
(10) Pub. No.: US 2020/0266113 A1
(43) Pub. Date: Aug. 20, 2020

(54) SEMICONDUCTOR STORAGE DEVICE AND INSPECTION METHOD

(71) Applicant: TOSHIBA MEMORY CORPORATION, Minato-ku (JP)

(72) Inventor: Akihiko TSUGAWA, Kuwana (JP)

(73) Assignee: TOSHIBA MEMORY CORPORATION, Minato-ku (JP)

(21) Appl. No.: 16/559,187

(22) Filed: Sep. 3, 2019

(30) Foreign Application Priority Data
Feb. 19, 2019 (JP) 2019-027850

(51) Int. Cl. H01L 21/66; H01L 27/11524; H01L 27/11556; H01L 27/11529; H01L 27/1157; H01L 27/11582; H01L 27/11573; H01L 23/522; H01L 23/528; H01L 23/535; G01R 31/02; G01R 31/305

(52) U.S. Cl. CPC H01L 22/12; H01L 27/11524; H01L 27/11556; H01L 27/11529; H01L 27/1157; G01R 31/305; H01L 27/11573; H01L 23/5226; H01L 23/5283; H01L 23/535; G01R 31/025; H01L 27/11582

(57) ABSTRACT

A semiconductor storage device of an embodiment includes a stacked body including a plurality of conductive layers stacked via insulating layers, and a step portion in which end portions of the plurality of conductive layers have a stepwise shape, a plurality of pillars extending in the stacked body in a stacking direction of the stacked body, and forming a plurality of memory cells at intersection portions with at least part the plurality of conductive layers, and a plurality of contacts disposed for respective steps of the step portion, and to be electrically connected with the conductive layers of the respective steps. Among the plurality of contacts, a first plug is disposed on a contact connected to an (n−1)-th (n is an integer of two or more) conductive layer from an undermost layer, and a second plug is disposed on the first plug, and among the plurality of contacts, the first plug is not disposed but the second plug is disposed on a contact connected to an n-th conductive layer from the undermost layer.

### CROSS-REFERENCE TO RELATED APPLICATIONS

This application is based upon and claims the benefit of priority from Japanese Patent Application No. 2019-027850, filed on Feb. 19, 2019; the entire contents of which are incorporated herein by reference.

### FIELD

Embodiments described herein relate generally a semiconductor storage device and an inspection method.

### BACKGROUND

In a three-dimensional nonvolatile memory, for drawing a plurality of stacked conductive layers, end portions of the conductive layers form a stepwise shape, and a plurality of contacts is disposed at the end portions. In this case, it is desired to accurately inspect whether or not a contact penetrates through a connection target conductive layer, and shorts out with a lower conductive layer.

### BRIEF DESCRIPTION OF THE DRAWING

FIGS. 1A and 1B are configuration examples of a semiconductor storage device according to an embodiment;

FIGS. 2A and 2B are cross-sectional views illustrating an example of a procedure of a manufacturing process of the semiconductor storage device according to an embodiment;

FIGS. 3A and 3B are cross-sectional views illustrating an example of a procedure of a manufacturing process of the semiconductor storage device according to an embodiment;

FIGS. 4A and 4B are cross-sectional views illustrating an example of a procedure of a manufacturing process of the semiconductor storage device according to an embodiment;

FIGS. 5A and 5B are cross-sectional views illustrating an example of a procedure of a manufacturing process of the semiconductor storage device according to an embodiment;

FIG. 6 is a cross-sectional view illustrating an example of a procedure of a manufacturing process of the semiconductor storage device according to an embodiment;

FIG. 7 is a cross-sectional view illustrating an example of a procedure of a manufacturing process of the semiconductor storage device according to an embodiment;

FIGS. 8A and 8B are schematic diagrams describing the principle of VC inspection according to an embodiment;

FIGS. 9A and 9B are schematic diagrams illustrating an observation image of each unit in VC inspection according to an embodiment;

FIG. 10 is a flowchart illustrating an example of a procedure of VC inspection according to an embodiment; and

FIGS. 11A and 11B are diagrams describing a semiconductor storage device according to a modified example of an embodiment.

### DETAILED DESCRIPTION

In general, according to one embodiment, a semiconductor storage device of an embodiment includes a stacked body including a plurality of conductive layers stacked via insulating layers, and being provided with a step portion in which end portions of the plurality of conductive layers have a stepwise shape, a plurality of pillars extending in the stacked body in a stacking direction of the stacked body, and forming a plurality of memory cells at intersection portions with at least part of the plurality of conductive layers, and a plurality of contacts disposed for respective steps of the step portion, and to be electrically connected with the conductive layers of the respective steps. Among the plurality of con ts, a first plug is disposed on a contact connected to an (n−1)-th (n is an integer of two or more) conductive layer from an undermost layer, and a second plug is disposed on the first plug, and among the plurality of contacts, the first plug is not disposed but the second plug is disposed on a contact connected to an n-th conductive layer from the undermost layer.

Exemplary embodiments of the present invention will be explained below in detail with reference to the accompanying drawings. In addition, the present invention is not limited to the following embodiments. In addition, components in the following embodiments include components that can be easily conceived by the one skilled in the art, or substantially the same components.

(Configuration Example of Semiconductor Storage Device)

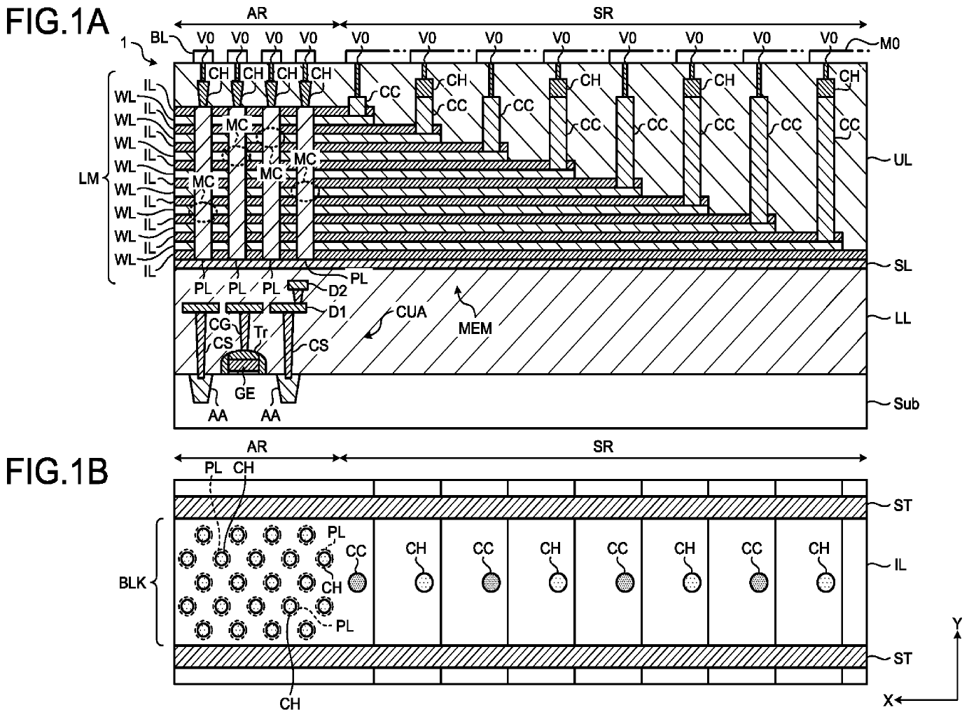

FIGS. 1A and 1B are configuration examples of a semiconductor storage device 1 according to an embodiment. FIG. 1A is a cross-sectional view extending along an X direction of the semiconductor storage device 1, and FIG. 1B is a plan view of the semiconductor storage device 1. Nevertheless, in FIG. 18, an insulating layer UL and a plug V0 that are provided in an upper part of a stacked body LM, and upper wire layers such as an upper wire M0 and a bit line BL are omitted.

In addition, in this specification, an up-down direction is defined based on the shape of an undermentioned step portion SR. Specifically, a direction toward which a terrace portion of the step portion SR, that is to say, an exposed surface of an interlayer insulating layer IL in each step of the step portion SR faces is regarded as an up direction.

As illustrated in FIGS. 1A and FIG. 1B, the semiconductor storage device 1 is formed as a three-dimensional nonvolatile memory including a memory portion MEM including a plurality of memory cells MC, and a peripheral circuit CUA disposed on the lower portion of the memory portion MEM.

The memory portion MEM includes the stacked body LM in which a plurality of word lines WL serving as conductive layers, and a plurality of interlayer insulating layers IL are alternately stacked. The numbers of the word lines WL and the interlayer insulating layers IL are not limited to the numbers in the example of FIG. 1A, and may be any number. In addition, the stacked body LM may include a selection gate line (not illustrated) disposed above the uppermost word line WL or below the undermost word line PL. The stacked body LM includes a cell array portion AR in which a plurality of memory cells MC is three-dimensionally disposed, and the step portion SR in which end portions of the word line L (and selection gate lines) constituting the stacked body LM form a stepwise shape.

The stacked body LM is segmentalized by a plurality of slits ST extending in the Y direction and a stacking direction of the stacked body LM so as to penetrate through from the uppermost word line WL to the undermost word line WL of the stacked body LM. The plurality of memory cells MC of the cell array portion AR is thereby divided into a plurality of blocks BLK arranged in a Y direction. The slit ST is filled with an insulating layer, for example. By further filling the slit ST with a conductive layer using an insulating layer as a liner, the lit ST may be used as a source line contact, for example.

In the cell array portion AR, pillars PL extending in the stacking direction of the stacked body LM are disposed so as to penetrate through from the uppermost word line WL to the undermost word line WL of the stacked body LM. The pillar PL includes a core layer, a channel layer, and a memory layer, and the channel layer is connected to a source line SL provided below the stacked body LM. The memory cells MC are thereby three-dimensionally arrayed at positions intersecting with the word lines WL, along a height direction of the pillars PL. By being supplied with a predetermined voltage from the word line WL located at the same height position, the memory cell MC holds data and also outputs the held data.

On a top surface of each of the pillars PL, a plug CH serving as a lower plug that is connected to the channel layer included in the pillar PL is disposed. On these plugs CH, plugs V0 each serving as upper plugs are disposed. A diameter of the plugs CH is larger than a diameter of the plugs V0. In other words, a cross-sectional area of the plugs CH in a direction going along a direction in which each layer of the stacked body LM extends is larger than a cross-sectional area of the plugs V0 in the direction going along the direction in which each layer of the stacked body LM extends. The channel layers of the pillars PL are electrically connected with the bit lines EL serving as an upper wire, at least via these plugs CH and V0.

The step portion SR is provided with a plurality of steps rising toward the cell array portion AR side in the X direction. Each step of the step portion SR incudes the one-layer word line WL and the one-layer interlayer insulating layer IL provided above the word line WL, for example. In each step of the step portion SR, a contact CC for achieving conduction with the word line WL of each step is arranged. For example, the contact CC may be formed of metal material, and barrier metal may be disposed around the contact CC. Each contact CC penetrates through the interlayer insulating layer IL constituting the step in which a corresponding contact CC is disposed, and is connected with the word line WL provided below the interlayer insulating layer IL. A set of the word line WL of each layer and the connected contact CC is provided for each block BLK, for example.

In this manner, on the top surfaces of the contacts CC for the steps of the word line WL that rise one layer by one layer, the plugs CH serving as a first plug are alternately disposed. The plug CH is formed of metal material, for example, and a barrier metal may be disposed around the plug CH. On these plugs CH, the plugs V0 serving as a second plug are disposed. For example, these plugs CH and V0 exist in the same hierarchy as the plugs CH and V0 disposed on the pillars FL in the cell array portion AR, and are disposed at substantially the same height using the same material. In other words, among the plurality of contacts CC provided on the respective steps in the step portion SR, partial contacts CC being a half thereof are electrically connected with the respective upper wires M0 at least via these plugs CH and V0.

On the other hand, on the top surfaces of the contacts CC on which the plugs CH are not disposed, the plugs V0 serving as the second plug are directly disposed, for example. The plug V0 is formed of metal material, for example, and a barrier metal may be disposed around the plug V0. For example, these plugs V0 exist over the hierarchy of the plugs CH and V0 disposed on the pillars PL in the cell array portion AR, and are disposed at substantially the same height as a height from the bottom surface of the plug CH to the top surface of the plug V0 on the pillar PL. In other words, among the plurality of contacts CC provided on the respective steps in the step portion SR, the remaining half contacts CC being a half thereof are electrically connected with the respective upper wires M0 at least via the plugs V0.

In other words, on the surface of the contact CC connected to an (n−1)-th (n is an integer of two or more) word line WL from the undermost layer, the plugs CH and V0 are disposed. On the top surface of the contact CC connected to an n-th word line WL front the undermost layer, the plug CH is not disposed but the plug V0 is disposed. A diameter of the plugs CH is larger than a diameter of the plugs V0. In other words, a cross-sectional area of the plugs CH in a direction going along a direction in which each layer of the stacked body LM extends is larger than a cross-sectional area of the plugs V0 in the direction going along the direction in which each layer of the stacked body LM extends.

In addition, the pillar PL and contact CC may include a plug other than the above-described plugs CH and V0 at the same height position. In other words, the pillar PL and contact CC may include another plug in a lower hierarchy than the plug CH. The pillar FL and contact CC may include another plug in a hierarchy between the plugs CH and VC.

The entire structure illustrated in FIG. 1B that includes the stacked body LM, the contact CC, and the plug CH are covered by the insulating layer UL.

The peripheral circuit CUA includes a transistor Tr contributing to an operation of the memory cell MC. The transistor Tr includes an active region AA provided on a wafer Sub such as a silicon substrate, and a gate electrode GE provided on the active region AA. A gate contact CG is connected to the gate electrode GE. Source drain contacts CS are connected to the active regions AA provided on the both sides of the gate electrode GE, that is to say, to a source region and a drain region. The source drain contact CS is connected to a wiring layer D1, and further connected to a wiring layer D2 or the like that is provided above the wiring layer D1, via another contact. These structures are entirely covered by an insulating layer LL.

(Example of Manufacturing Process of Semiconductor Storage Device)

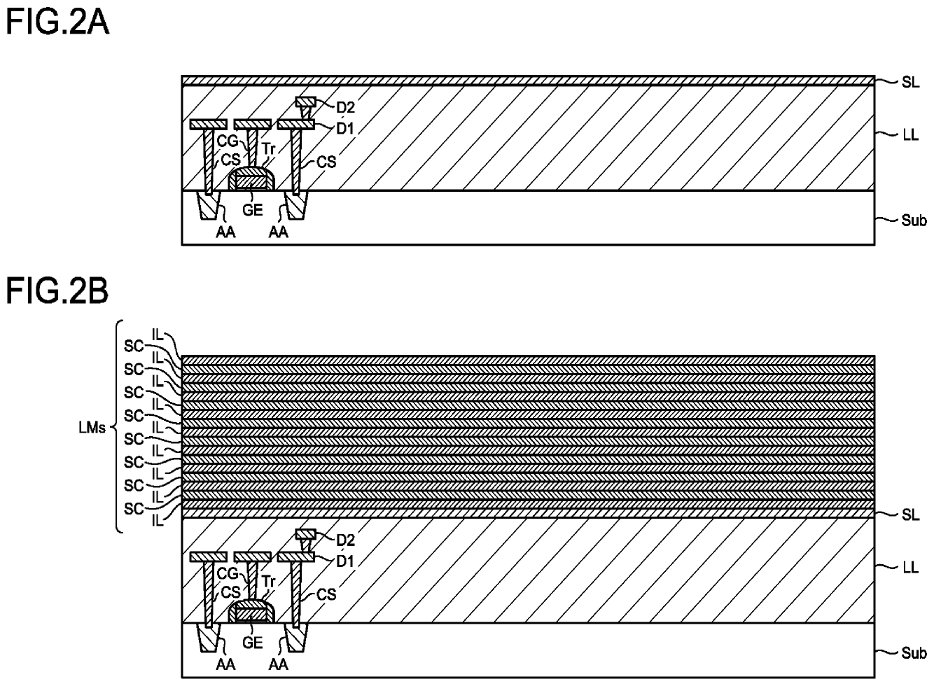

Next, examples of a manufacturing process of the semiconductor storage device 1 of the embodiment will be described using FIGS. 2A to 7. FIGS. 2A to 7 are cross-sectional views each illustrating an example of a procedure of a manufacturing process of the semiconductor storage device 1 according to an embodiment.

As illustrated in FIG. 2A, the active region AA is formed by diffusing impurities in the wafer Sub such as a silicon substrate. The transistor Tr is formed on the active region AA. The gate contact CG connected to the gate electrode GE of the transistor Tr, and the source drain contact CS connected to the active region AA are formed. The wiring layers D1 and D2 are formed on the source drain contact CS via another contact. The insulating layer LL entirely covering these structures is formed on the wafer Sub. The source line SL is formed on the insulating layer LL.

As illustrated in FIG. 2B, a stacked body LMs in which a plurality of sacrificial layers SC and a plurality of interlayer insulating layers IL are alternately stacked is formed. The sacrificial layer SC is a layer replaceable with conductive material such as tungsten in a subsequent process.

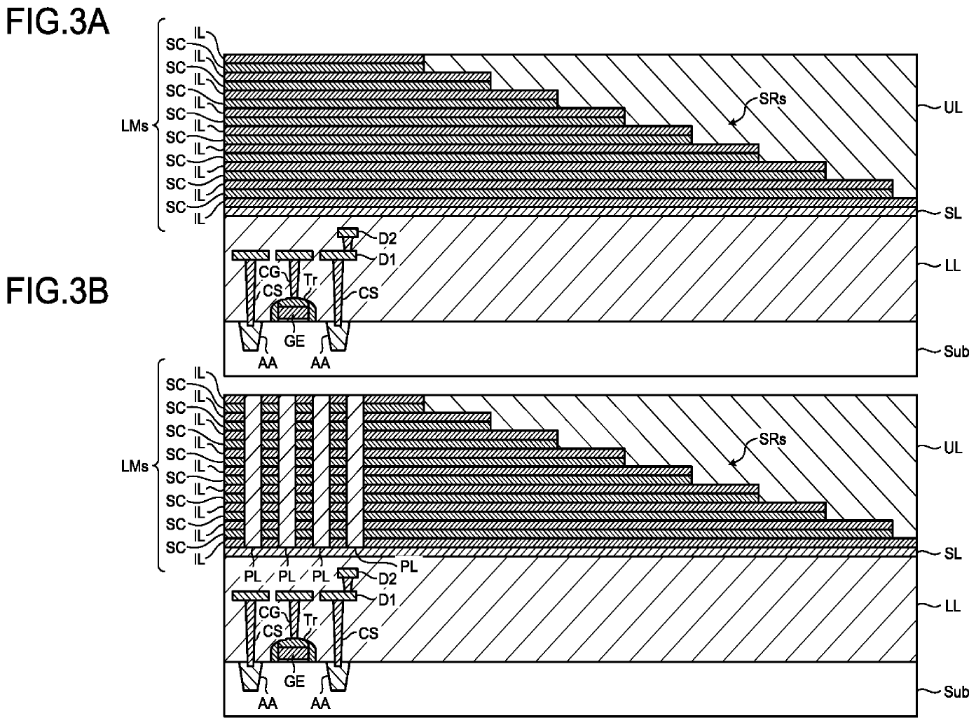

As illustrated in FIG. 3A, a step portion SRs including one pair of the sacrificial layer SC and the interlayer insulating layer IL as one step is formed. The insulating layer UL is formed so as to cover the step portion SRs.

As illustrated in FIG. 3B, the pillar PL extending in the stacking direction of the stacked body LMs is formed so as to penetrate through the stacked body LMs. The pillar PL is formed by forming a memory hole penetrating through the stacked body LMs, and filling the memory hole with a memory layer, a channel layer, and a core layer in order from an inner wall side of the memory hole. The channel layer is formed also on a bottom portion of the memory hole. The channel layer and the source line SL are thereby connected.

After the formation of the pillar PL, a plurality of slits ST (refer to FIG. 1B extending in the X direction and segmentalizing the stacked body LMs in the Y direction is formed. At this time, the slit ST is not filled with an insulating layer or the like, and the slit ST has a groove shape penetrating through the stacked body LMs.

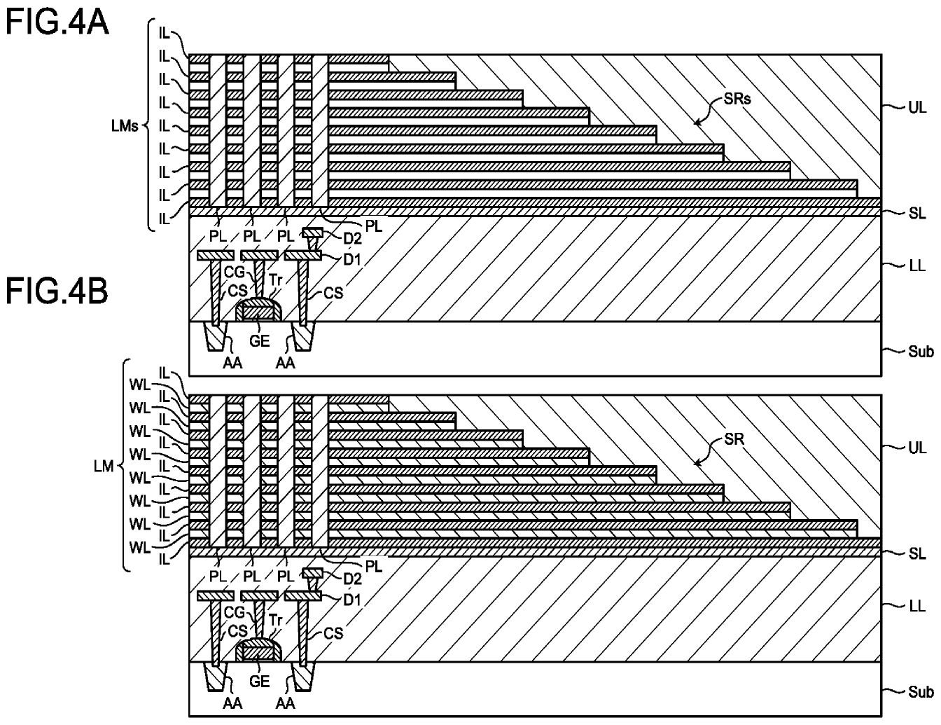

As illustrated in FIG. 4A, the sacrificial layer SC of the stacked body LMs is removed via the groove-shaped slit ST. A gap is formed between the interlayer insulating layers IL from which the sacrificial layers SC are removed.

As illustrated in FIG. 4B, the gap formed between the interlayer insulating layers IL is filled with conductive material via the groove-shaped slit ST, and a plurality of word lines WL to be stacked between the interlayer insulating layers L are formed. After that, the slit ST is filled with an insulating layer, or an insulating layer and a conductive layer.

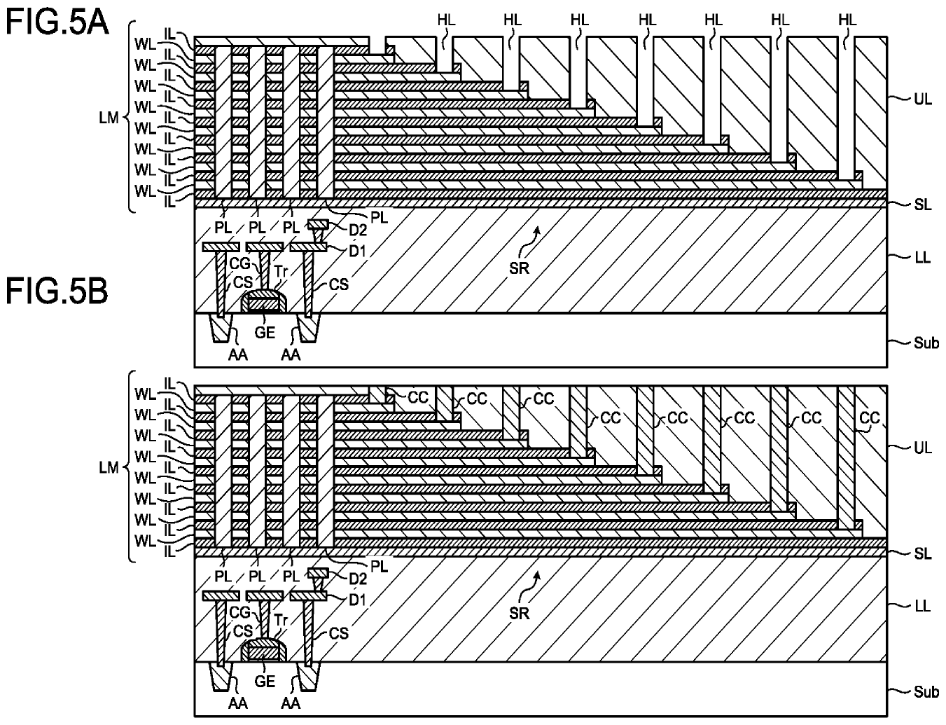

As illustrated in FIG. 5A, after the insulating layer UL is formed to be further thicker so as to cover the uppermost layer of the stacked body LM, a contact hole HL penetrating through the insulating layer UL and reaching the word line WL forming each step of the step portion SR is formed.

As illustrated in FIG. 5B, by filling each of the contact holes HL with conductive material such as tungsten, a plurality of contacts CC respectively connecting to the word lines WL of the respective steps is formed. The plurality of contacts CC may be formed using barrier metal as a liner.

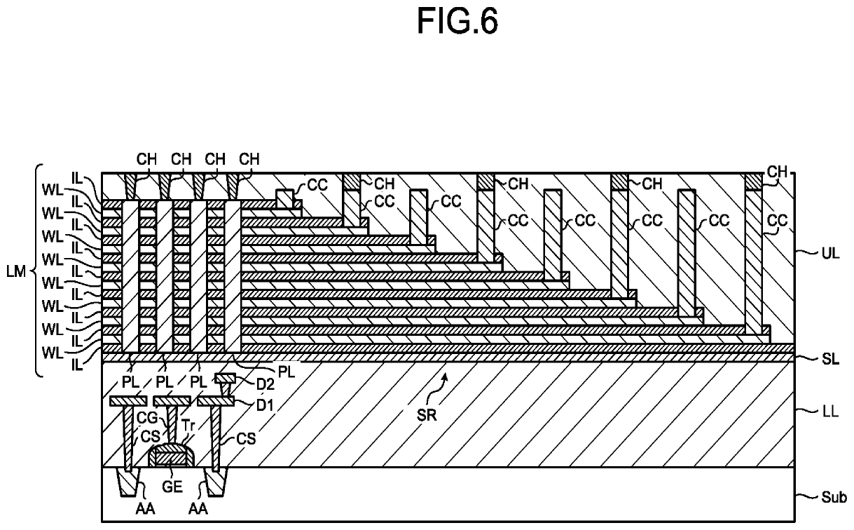

As illustrated in FIG. 6, the plugs CH are formed on all the pillars PL and alternate contacts CC inside the further thickened insulating layer UL. With this configuration, in the step portion SR, the contacts CC having the plugs CH exposed to the surface layer, and the contacts CC having the top surfaces covered by the insulating layer UL are alternately arranged in the direction. In addition, the plugs CH may be formed using barrier metal as a liner. In addition, a thickness of the insulating layer UL covering the top surface of a predetermined contact CC is preferably about 100 nm to 200 nm, for example.

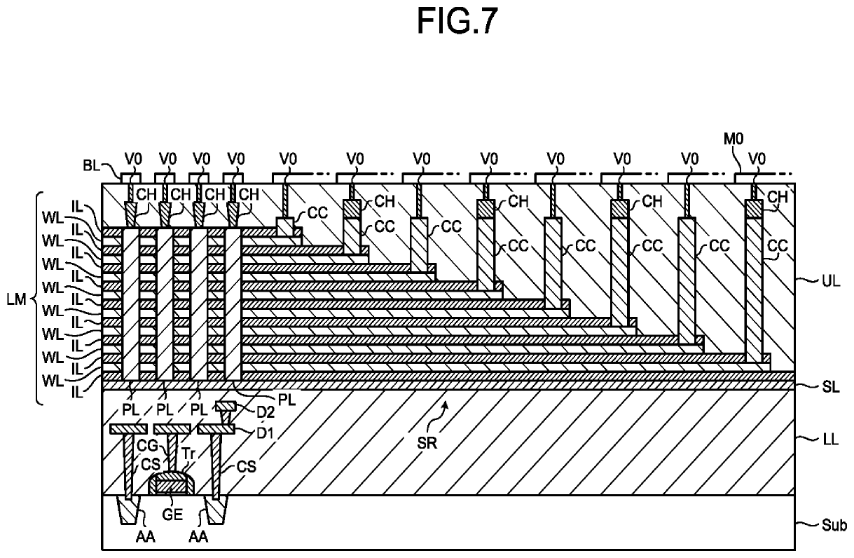

As illustrated in FIG. 7, the plugs V0 are formed over all the pillars PL and all the contacts CC inside the further thickened insulating layer UL. The plugs V0 may be formed using barrier metal as a liner. In addition, the bit line BL and the upper wire M0 connected to the plug V0 are formed. With this configuration, all the pillars PL and all the contacts CC are electrically connected to the upper wire layer at least via the plug V0. In other words, all the pillars PL and all the contacts CC are electrically connected to the upper wires including the bit line BL and the upper wire M0 via both the plugs CH and the plugs V0 that are bodies different from the plugs CH or via the plugs V0 each of which is formed by one body.

Through the above processes, the manufacturing process of the semiconductor storage device 1 of the embodiment ends.

Meanwhile, in the formation of the contact hole HL in FIG. 5A, such a formation failure of the contact hole HL that the contact hole HL penetrates through the targeted word line WL, and the bottom surface reaches the underlying word line WL may be generated. If such a contact hole HL is filled with conductive material and the contact CC is formed, the contact CC is electrically connected with both of the connection target word line ML and the underlying word line WL, and a short circuit is generated between these word lines WL.

Thus, for detecting a short circuit between the word lines WL that is caused by the contact CC penetrating through the connection target word line WL, Voltage Contrast (VC) inspection that uses potential contrast is performed. The VC inspection is performed in the state in FIG. 6 in which the plugs CH are alternately formed on the contacts CC.

(Examples of VC Inspection)

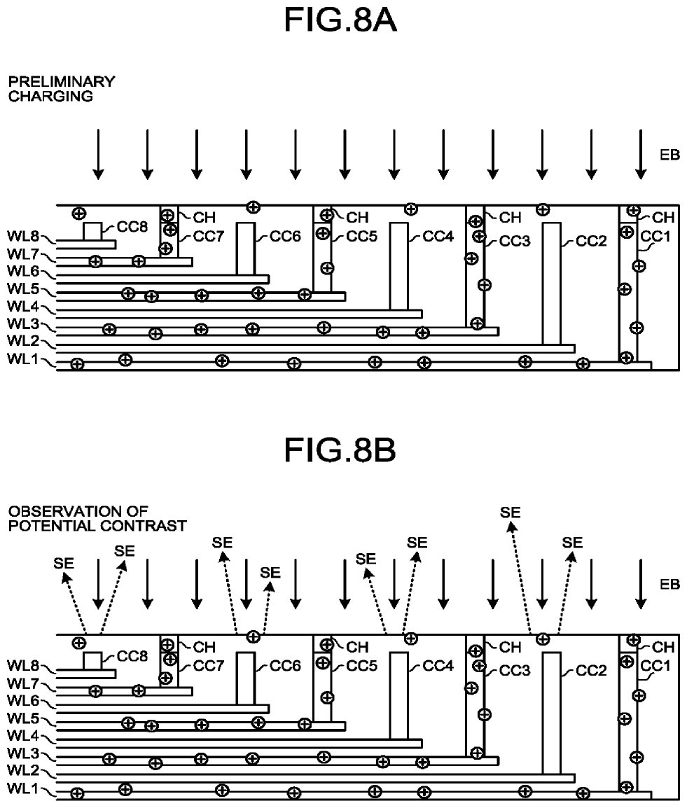

Next, examples of VC inspection will be described using FIGS. 8A to 10. Hereinafter, word lines WL will be referred to as word lines WL1, WL2, WL3, and so on from the lower layer side of the stacked body LM. In addition, contacts CC connected to these word lines WL1, WL2, WL3 and so on will be referred to as contacts CC1, CC2, CC3 and so on.

A VC inspection device used for VC inspection includes an electron gun that emits electron beams, and a detector that detects secondary electrons discharged from the surface of the wafer Sub or the like. As such a VC inspection device, for example, a defect review scanning electron microscope (DR-SEM), a critical dimension scanning electron microscope (CD-SEM), and the like can be used.

FIGS. 8A and 8B are schematic diagrams describing the principle of VC inspection according to an embodiment. As illustrated in FIGS. 8A and 8B, in the VC inspection, for example, preliminary charging and the observation of potential contrast being main inspection are executed.

As illustrated in FIG. 8A, by performing preliminary charging, the wafer Sub, more specifically, the surface layer portion of the step portion SR of the semiconductor storage device 1 is charged positively. More specifically, landing energy of an electron beam EB is set to 0.3 keV, for example, and probe current is set to high current of 250 nA, for example. Such a condition is a condition under which the number of secondary electrons discharged from the wafer Sub becomes larger than the number of electrons emitted onto the wafer Sub. In other words, under the condition, a secondary electron generation efficiency, which is a ratio between discharged secondary electrons and emitted electrons exceeds one. With this configuration, the surface layer portion of the step portion SR is charged positively.

At this time, in the contacts CC1, CC3, CC5, and CC7 having the plugs CH exposed to the surface layer, the contacts CC1, CC3, CC5, and CC7, and the word lines WL1, WL3, WL5, and WL7 connected thereto are also charged positively via the plugs CH.

On the other hand, the contacts CC2, CC4, CC6, and CC8 having the surfaces covered by the insulating layer UL, and the word lines WL2, WL4, WL6, and WL8 connected thereto are hardly charged positively.

As illustrated in FIG. 8B, by causing the secondary electron SE to be discharged from a predetermined contact CC of the step portion SR, and detecting the secondary electron SE, observation of potential contrast is performed. More specifically, landing energy of an electron beam EB is set to 2 keV to 5 keV, for example, and the surface layer portion of the step portion SR is negatively charged. Such a condition is a condition under which potential contrast is obtained through the insulating layer UL having a thickness of about 100 nm to 200 nm for that covers a partial contact CC.

The contacts CC1, CC3, CC5, and CC7, and the word lines WL1, WL3, WL5, and WL7 are charged positively by preliminary charging. Thus, in the observation of potential contrast, the secondary electron SE generated in the surface layer portion of the contacts CC1, CC3, CC6, and CC7 by the emission of the electron beam ER gets trapped in the positively-charged portion, and is hardly discharged. Thus, in the VC inspection device, each portion of contacts CC1, CC3, CC5, and CC7 is observed to be dark.

The contacts CC2, CC4, CC6, and CC8, and the word lines WL2, WL4, WL6, and WL8 are hardly charged positively by preliminary charging. Thus, in the observation of potential contrast, the secondary electron SE generated in the surface layer portion of the contacts CC2, CC4, CC6, and CC8 is largely discharged. Thus, in the VC inspection device, each portion of contacts CC2, CC4, CC6, and CC8 is observed to be light.

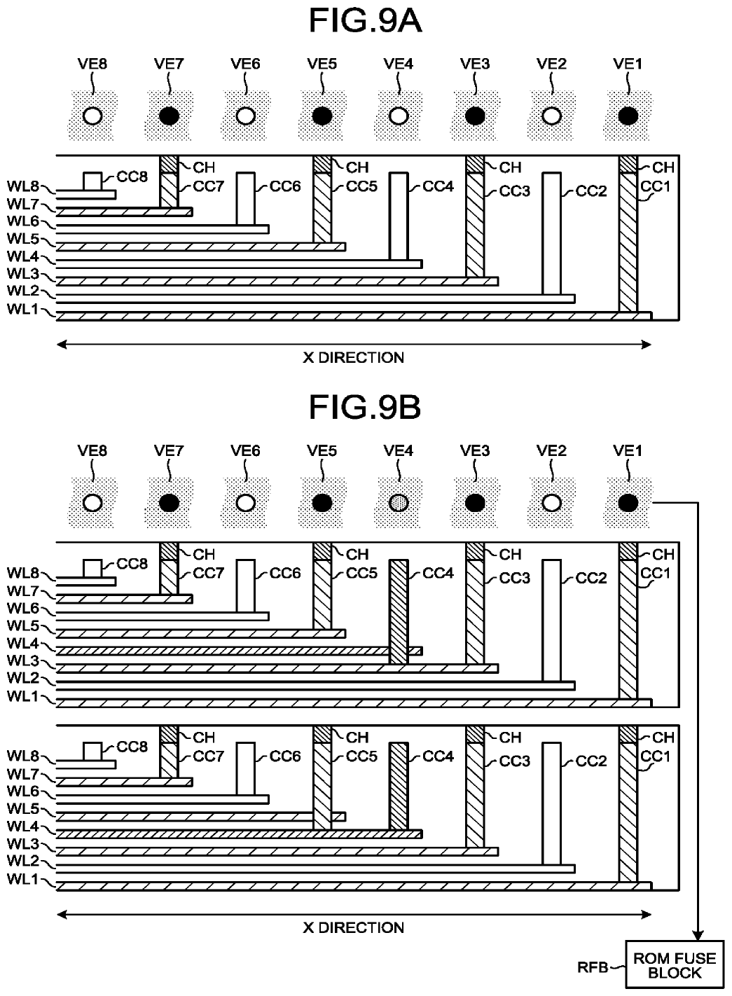

FIGS. 9A and 9E are schematic diagrams illustrating an observation image of each unit in VC inspection according to an embodiment.

As illustrated in FIG. BA, if each contact CC is connected only to a connection target word line WL as intended, between the contacts CC1, CC3, CC5, and CC7 having the plugs CH, and the contacts CC2, CC4, CC6, and CC8 not having the plugs CH, light and dark caused by potential contrast are alternately observed in the X direction.

In other words, in the contacts CC1, CC2, CC5, and CC7 having the plugs CH, the secondary electron SE is hardly discharged, and observation images VE1, VE3, VE5, and VE7 look dark. In the contacts CC2, CC4, CC6, and CC8 not having the plugs CH, the secondary electron SF is largely discharged, and observation images VE2, VE4, VE6, and VE8 look light.

As illustrated in FIG. 9B, if at least any one of the contacts CC penetrates through the connection target word line WL, and is electrically connected to the underlying word line WL, regularity of dark and light in the X direction that is caused by potential contrast is impaired. In the example in FIG. 9B, the observation image VE4 that is to look light looks slightly dark. In this case, two states are assumed.

As illustrated in an upper part in FIG. 9B, the first state is a state in which the contact CC4 to be connected to the word line WL4 penetrates through the word line WL4, and is electrically connected with the underlying word line WL3. In this case, in preliminary charging, the contact CC4 and the word line WL4 are charged positively via the word line WL3, and a discharge amount of the secondary electron SE in the observation of potential contrast is considered to be decreased.

As illustrated in a lower part in FIG. 9B, the second state is a state in which the contact CC5 to be connected to the word line WL5 penetrates through the word line WL5, and is electrically connected with the underlying word line WL4. In this case, in preliminary charging, the contact CC4 and the word line WL4 are charged positively via the word line WL5, and a discharge amount of the secondary electron SE in the observation of potential contrast is considered to be decreased.

In this manner, by regularity of potential contrast in the X direction being impaired, that is to say, by any observation image VE that is to look light looking darker at least than usual, it is detected that a short circuit between hierarchies is generated above or below the dark image, that is to say, near the word lines WL3 to WL5 in the example in FIG. 9B.

Such VC inspection is executed for each block BLK, for example, and the presence or absence of the generation of a short circuit in the word line WL is determined for each block BLK. A block BLK in which a short circuit is generated is managed as an unusable bad block in the completed semiconductor storage device 1. The semiconductor storage device 1 includes a ROM fuse block RFB as a registration destination of bad block information, for example.

The ROM fuse block RFB is an aggregate of fuse elements that can each electrically write information only once, and is provided in the semiconductor storage device 1 as a management region of the memory portion MEM including a plurality of memory cells MC. The ROM fuse block RFB stores various types of information regarding the semiconductor storage device 1 such as redundancy data of the memory cell MC and bad block information. These pieces of information are read out when power of the semiconductor storage device 1 is input, and are used for controlling various operations of the memory portion MEM.

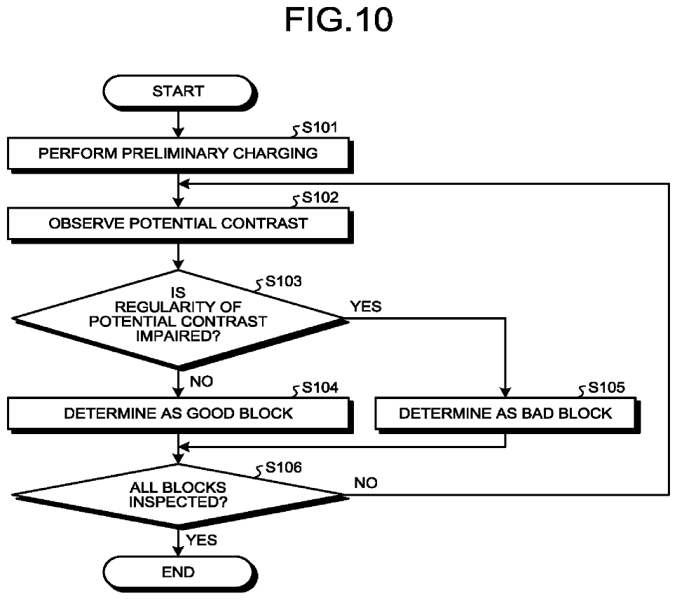

FIG. 10 is a flowchart illustrating an example of a procedure of VC inspection according to an embodiment, and the VC inspection of the embodiment is executed a one process of the manufacturing process of the semiconductor storage device 1, for example.

As illustrated in FIG. 10, preliminary charging is executed on the contacts CC of the step portion SR disposed in all the blocks ELK on the entire wafer Sub (Step 101). Among all the blocks BLK on the entire wafer Sub, the observation of potential contrast is executed on the contact CC in a predetermined block BLK (Step S102), and whether regularity of potential contrast is impaired or not is detected (Step S103).

If regularity of potential contrast is not impaired (Step S103: No), it is determined that a short circuit is not generated by the contact CC penetrating through the word line WL, and an inspection target block BLK is determined as a good block (Step S104).

If regularity of potential contrast is impaired (Step S103: Yes), it is determined that a short circuit is generated by any of the contacts CC penetrating through the word line WL, and an inspection target block BLK is determined as a bad block (Step S105).

It is determined whether VC inspection has been executed on all blocks BLK (Step S106). If there is block BLK on which VC inspection is not executed (Step S106: No), processes from Step S102 are repeated. If VC inspection has been executed on ail blocks BLK (Step S106: Yes), VC inspection ends.

As described above, in a semiconductor storage device, in a process of forming a contact of a step portion, a short circuit is sometimes generated between a plurality of word lines. A case of detecting, by VC inspection, such a short circuit between hierarchies of word lines in a state immediately after contact formation, that is to say, at the stage corresponding to FIG. 5B described above will be considered.

In each contact, a depth from the top surface of the contact to the bottom surface varies. When VC inspection is performed in a state in which all contacts are exposed to a surface layer portion above a step portion, if each contact is formed at appropriate depth, by increasing a positive charge amount held by a contact from a shallow contact to a deep contact, it is considered that observation images getting gradually darker are obtained.

Nevertheless, actually, as described above, not only contacts but also word lines are charged positively. Because capacitance at which a word line can hold positive charge is much larger than that of a contact, it becomes almost impossible to detect potential contrast caused by a difference in contact depth.

In the semiconductor storage device 1 of the embodiment, the plugs CH are alternately formed on the contacts CC of the step portion SR. By performing the VC inspection in such a state, the generation of a short circuit can be detected depending on whether observation images with regular potential contrast in the X direction can be obtained.

In addition, in the semiconductor storage device 1 of the embodiment, for detecting an open of the contact CC that is generated by the contact hole HL being formed so as not to reach the connection target word line WL, VC inspection may be executed at a stage corresponding to FIG. 5B described above. In this case, for example, in the opened contact CC, because positive charge is not sucked into the word line WL in preliminary charging and the positive charge on the surface does not decrease, the amount of the secondary electrons S1 trapped in the positively-charged portion is large in observing potential contrast, and observation images in VC inspection look dark. It is therefore possible to detect the open of the contact CC.

In the semiconductor storage device 1 of the embodiment, it is possible o detect generation of a short circuit by VC inspection more easily and accurately. For example, unlike electric property inspection performed after the end of a manufacturing process, good or bad determination can be performed at a relatively earlier stage. In addition, unlike destruction inspection or the like using a cross-sectional SEM or the like, it is possible to inspect all blocks, and detect generation of a short circuit more surely.

In the semiconductor storage device 1 of the embodiment, the manufacturing process originally includes a formation process of the plugs CH. Only by adjusting the manufacturing process in such a manner that the plugs CH are alternately formed on the contacts CC, a structure that can detect generation of a short circuit caused by the contact CC in VC inspection is enabled. It is unnecessary to add a new process to the manufacturing process, and it is possible to suppress an increase in cost or hassle of the manufacturing process.

In the semiconductor storage device 1 of the embodiment, the plugs V0 are formed on all the contacts CC of the step portion SR. With this configuration, even the contact CC not having the plug CH can be electrically connected with the upper wire M0. It is unnecessary to add a new process to the manufacturing process, and it is possible to suppress an increase in cost or hassle of the manufacturing process.

(Modified Example)

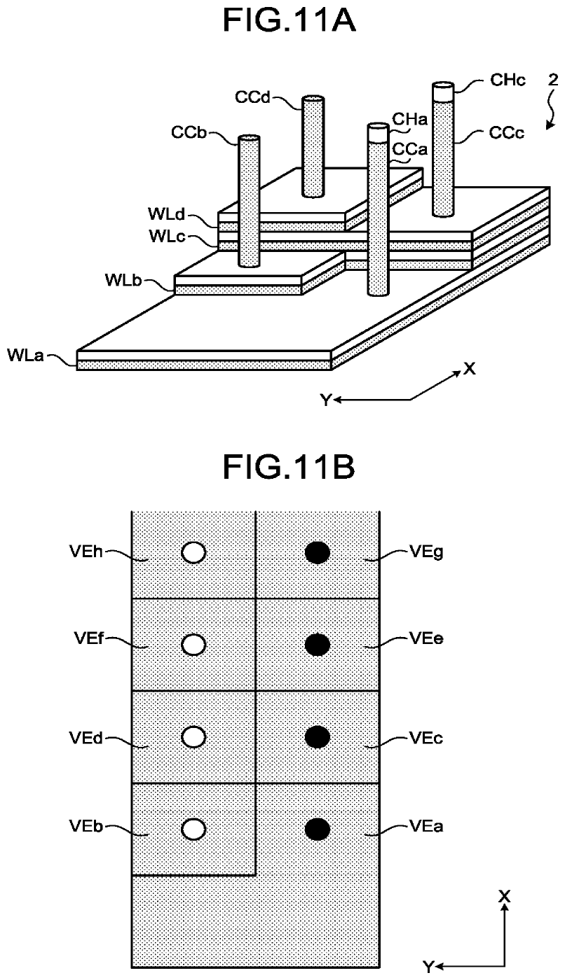

Next, a semiconductor storage device of a modified example of the embodiment will be described using FIGS. 11A and 11B. FIGS. 11A and 11B are diagrams describing a semiconductor storage device 2 according to a modified example of an embodiment. The semiconductor storage device of the modified example differs from the aforementioned embodiment in that light and dark of observation images VE caused by VC inspection are alternately arranged in the Y direction.

As illustrated in a perspective view in FIG. 11A, in the semiconductor storage device 2 of the modified example, steps of a step portion rise not only in the X direction but also in the Y direction. In the Y direction, for example, steps rise one layer by one layer of the word lines WL, and in the X direction, for example, steps rise two layers by two layers of the word lines WL.

In other words, the number of stacked layers increases from an undermost word line WLa like a word line WLb, WLc, WLd, and so on. Contacts CCa, CCb, CCc, CCd, and so on are disposed for the respective step so as to correspond to these word lines WLa, WLb, WLc, WLd, and so on. Among these, alternate contacts CCa, CCc, and so on respectively include plugs CHa, CHc, and so on serving as the first plug. In addition, all contacts CC include second plugs (not illustrated) connected to the upper wire M0.

As illustrated in a plan view in FIG. 11B, in the semiconductor storage device 2 of the modified example, light and dark are alternately arranged in the Y direction in the VC inspection as follows. More specifically, an observation image VEa corresponding to the contact CCa having the plug CHa is dark, an observation image VEb corresponding to the contact CCb not having a plug is light, and an observation image VEc corresponding to the contact CCc having the plug CHc is dark. On the other hand, observation images VEa, VEc, VEe, VEg, and so on arranged in the X direction look dark, and observation images VEb, VEd, VEf, VEh, and so on look light.

Also in the semiconductor storage device 2 of the modified example, observation images VEa, VEb, VEc, and so on of the VC inspection have predetermined regularity, and it is possible to detect whether a short circuit is generated between any of the word lines WLa, WLb, WLc, and so on, depending on whether the regularity of these is maintained.

As described above, patterns of regularity of observation images may vary in diverse ways depending on the arrangement of steps of the step portion. By the observation images having regularity of some sort, it is possible to detect a short circuit in word lines.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a stacked body including a plurality of conductive layers stacked via insulating layers, the stacked body being provided with a step portion in which end portions of the plurality of conductive layers have a stepwise shape;
a plurality of pillars extending in the stacked body in a stacking direction of the stacked body, and forming a plurality of memory cells at intersection portions with at least part of the plurality of conductive layers; and
a plurality of contacts disposed for respective steps of the step portion, and to be electrically connected with the conductive layers of the respective steps,
wherein, among the plurality of contacts, a first plug is disposed on a contact connected to an (n−1)-th (n is an integer of two or more) conductive layer from an undermost layer, and a second plug is disposed on the first plug, and
wherein, among the plurality of contacts, the first plug is not disposed but the second plug is disposed on a contact connected to an n-th conductive layer from the undermost layer.

2. The semiconductor storage device according to claim 1,
wherein the plurality of pillars is electrically connected with a plurality of bit lines via a lower plug formed in a first hierarchy in which the first plug is disposed, and an upper plug formed in a second hierarchy in which the second plug on the first plug is disposed.

3. The semiconductor storage device according to claim 2,
wherein the contact connected to the (n−1)-th conductive layer is electrically connected with a first upper wire via the first plug disposed in the first hierarchy, and the second plug disposed in the second hierarchy, and
wherein the contact connected to the n-th conductive layer is electrically connected with a second upper wire via the second plug disposed over two hierarchies including the first hierarchy and the second hierarchy.

4. The semiconductor storage device according to claim 1, comprising
a plurality of memory blocks and a management region for the plurality of memory cells,
wherein the plurality of memory cells belongs to any of the memory blocks,
wherein the plurality of contacts is provided for the respective memory blocks to correspond to the conductive layers of the respective steps, and
wherein, in the plurality of contacts provided for the respective memory blocks, a memory block including a contact connected to a conductive layer not to be electrically connected is registered as a bad block in the management region.

5. The semiconductor storage device according to claim 1, wherein
a cross-sectional area of the first plug is larger than a cross-sectional area of the second plug.

6. The semiconductor storage device according to claim 1, wherein
the plurality of conductive layers alternately includes, in the stacking direction, first conductive layers respectively connected with contacts on which the first plugs and the second plugs are disposed, among the plurality of contacts, and second conductive layers respectively connected with contacts on which the second plugs are disposed not via the first plugs, among the plurality of contacts.

7. The semiconductor storage device according to claim 1, wherein
a length in the stacking direction of the second plug on the contact connected to the n-th conductive layer corresponds to a total length of a length in the stacking direction of the first plug, and a length in the stacking direction of the second plug on the contact connected to the (n−1)-th conductive layer.

8. A semiconductor storage device comprising:
a stacked body including a plurality of conductive layers stacked via insulating layers, the stacked body being provided with a step portion in which end portions of the plurality of conductive layers have a stepwise shape;
a plurality of pillars extending in the stacked body in a stacking direction of the stacked body, and forming a plurality of memory cells at intersection portions with at least part of the plurality of conductive layers;
a plurality of contacts disposed for respective steps of the step portion, and to be electrically connected with the conductive layers of the respective steps;
an upper wire layer including a first upper wire and a second upper wire disposed in a same hierarchy;
a first connection portion disposed between the firs upper wire and a first contact connected to an (n−1)-th (n is an integer of two or more) conductive layer from an undermost layer among the plurality of contacts; and
a second connection portion disposed between the second upper wire and a second contact connected to an n-th conductive layer from the undermost layer among the plurality of contacts,
wherein the second connection portion includes a plug member extending in the stacking direction between a first level and a second level in the stacking direction, and formed by one body, and
wherein the first connection portion includes a first lower plug member extending in the stacking direction between the first level and a third level in the stacking direction, and a first upper plug member extending in the stacking direction between the third level and the second level in the stacking direction, the third level is positioned between the first level and the second level in the stacking direction and the first lower plug member and the first upper plug member are formed by a body different from each other, and one ends of the first lower plug member and the first upper plug member are coupled.

9. The semiconductor storage device according to claim 8, further comprising
a third connection portion disposed between one of the pillars and a third upper wire included in the upper wire layer,
wherein the third upper wire is disposed in the same hierarchy as the first upper wire and the second upper wire, and
wherein the third connection portion includes a second lower plug member extending in the stacking direction between the first level and the third level in the stacking direction, and a second upper plug member extending in the stacking direction between the third level and the second level in the stacking direction, the second lower plug member and the second upper plug member are formed by different bodies, and one ends of the second lower plug member and the second upper plug member are coupled.

10. The semiconductor storage device according to claim 9, wherein
the third upper wire is a bit line.

11. The semiconductor storage device according to claim 8, comprising
a plurality of memory blocks and a management region for the plurality of memory cells,
wherein the plurality of memory cells belongs to any of the memory blocks,
wherein the plurality of contacts is provided for the respective memory blocks to correspond to the conductive layers of the respective steps, and
wherein, in the plurality of contacts provided for the respective memory blocks, a memory block including a contact connected to a conductive layer not to be electrically connected is registered as a bad block in the management region.

12. The semiconductor storage device according to claim 8, wherein
a cross-sectional area of the first lower plug member is larger than a cross-sectional area of the first upper plug member.

13. The semiconductor storage device according to claim 9, wherein
a cross-sectional area of the second lower plug member is larger than a cross-sectional area of the second upper plug member.

14. An inspection method to be executed in a manufacturing process of a semiconductor storage device including:
a stacked body including a plurality of conductive layers stacked via insulating layers, the stacked body being provided with a step portion in which end portions of the plurality of conductive layers have a stepwise shape;
a plurality of pillars extending in the stacked body in a stacking direction of the stacked body, and forming a plurality of memory cells at intersection portions with at least part of the plurality of conductive layers; and
a plurality of contacts disposed for respective steps of the step portion, and to be electrically connected with the conductive layers of the respective steps,
the inspection method comprising:
emitting an electron beam to:
a first contact connected to an (n−1)-th (n is an integer of two or more) conductive layer from an undermost layer among the plurality of contacts, and having a plug exposed to a surface layer that is disposed on a top surface of the first contact;
a second contact connected to an n-th conductive layer from the undermost layer among the plurality of contacts, and having a top surface covered by an insulating layer; and
a third contact connected to an (n+1)-th conductive layer from the undermost layer among the plurality of contacts, and having a plug exposed to a surface layer that is disposed on a top surface of the third contact; and
determining whether a short circuit is generated between hierarchies on at least the n-th conductive layer connected to the second contact, based on potential contrast generated in the first contact, the second contact, and the third contact.

15. The inspection method according to claim 14,
wherein the electron beam is further emitted to a fourth contact connected to an (n+2)-th conductive layer from the undermost layer among the plurality of contacts, and having a top surface covered by an insulating layer, and
wherein it is determined whether a short circuit is generated between hierarchies on the conductive layers connected to the first to the fourth contacts, based on whether light and dark observed in each of the first contact, the second contact, the third contact, and the fourth contact are regularly arrayed.

16. The inspection method according to claim 14,
wherein, in a case where a short circuit is not generated between hierarchies on the n-th conductive layer connected to the second contact, the second contact irradiated with the electron beam is observed at first lightness, and the first contact and the third contact irradiated with the electron beam are observed at second lightness lower than the first lightness, and
wherein, in a case where a short circuit is generated between hierarchies on the n-th conductive layer connected to the second contact, the second contact irradiated with the electron beam is observed at third lightness that is lower than the first lightness and is equal to or larger than the second lightness.

17. The inspection method according to claim 16,
wherein, in a case where a short circuit is not generated between hierarchies on the n-th conductive layer connected to the second contact, a secondary electron is observed with a first discharge amount from the second contact irradiated with the electron beam, and a secondary electron is observed with a second discharge amount smaller than the first discharge amount, from the first contact and the third contact irradiated with the electron beam, and
wherein, in a case where a short circuit is generated between hierarchies on the n-th conductive layer connected to the second contact, a secondary electron is observed with a third discharge amount that is smaller than the first discharge amount and is equal to or larger than the second discharge amount, from the second contact irradiated with the electron beam.

18. inspection method according to claim 14, wherein
a case where a short circuit is generated between hierarchies on the n-th conductive layer connected to the second contact includes:
a case where the second contact penetrates through the n-th conductive layer and reaches the (n−1)-th conductive layer, or
a case where the third contact penetrates through the (n+1)-th conductive layer and reaches the n-th conductive layer.

19. The inspection method according to claim 14, wherein
when the electron beam is emitted,
after at least the first contact and the third contact are charged positively,
electrons discharged from the first contact, the second contact, and the third contact are detected.

20. The inspection method according to claim 14,
wherein the semiconductor storage device includes a plurality of memory blocks,
wherein the plurality of memory cells belongs to any of the memory blocks,
wherein the plurality of contacts is provided for the respective memory blocks to correspond to the conductive layers of the respective steps, and
wherein it is determined whether short circuit is generated between hierarchies on the n-th conductive layer connected to the second contact, in each memory block of the plurality of memory block.
